(19) United States
(12) Patent Application Publication
(10) Pub. No.: US 2025/0201761 A1
(43) Pub. Date: Jun. 19, 2025

(54) SELF-ALIGNING SEMICONDUCTOR CONSTRUCTION

(71) Applicant: Intel Corporation, Santa Clara, CA (US)

(72) Inventors: Carlton Hanna, Santa Clara, CA (US); Bernd Waidhas, Pettendorf (DE); Jan Proschwitz, Riesa (DE); Sonja Koller, Lappersdorf (DE); Abdallah Bacha, Munich (DE)

(21) Appl. No.: 18/544,504

(22) Filed: Dec. 19, 2023

(51) Int. Cl. H01L 23/00; H01L 25/00; H01L 25/18; H10B 80/00

(52) U.S. Cl. CPC H01L 24/81; H01L 24/05; H01L 24/16; H01L 24/17; H01L 25/18; H01L 25/50; H10B 80/00; H01L 2224/0557; H01L 2224/16165; H01L 2224/16238; H01L 2224/17181; H01L 2224/81143; H01L 2224/81815

(57) ABSTRACT

A device may include a carrier with a plurality of first bump pads. The device may include a first die with a plurality of second bump pads. The device may include a plurality of first bumps disposed between the plurality of first bump pads and the plurality of second bump pads to electrically connect the first die to the carrier. The device may include solder disposed between the plurality of first bump pads and the plurality of second bump pads, wherein the plurality of first bump pads have a first pitch relative to one another, and the plurality of second bump pads have a second pitch relative to one another, and wherein the first pitch is different from the second pitch. Each first bump pad of the plurality of first bump pads is larger than each second bump pad of the plurality of second bump pads.

### BACKGROUND

In high performance semiconductor applications, heterogenous integration of silicon disaggregation or chiplets has emerged as an approach to improve total device performance with larger silicon area and increase silicon densities with multi-stacking in packages. The variety of advanced packaging technologies include 2D multi-chip on organic substrate packages, 2.3D side-by-side interconnect with organic interposer, 2.5D side-by-side interconnect with silicon bridges and interposers, and 3D stacking with active dies stacked vertically. Total performance gains are made possible with high-speed wire interconnects between dies, and these high-speed wire interconnects require higher densities and finer pitch to prevent impeding the device performance.

Therefore, there is a need for finer pitch interconnects in vertically stacked 3D devices or 2.5D bridge or interposer devices.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a flow chart illustrating a method of forming a semiconductor device according to an aspect of the present disclosure;

FIG. 2 shows a cross-sectional view of a semiconductor carrier according to an aspect of the present disclosure;

FIG. 3 shows a cross-sectional view of a semiconductor device according to an aspect of the present disclosure;

FIG. 4 shows a top-down view of a semiconductor device according to an aspect of the present disclosure;

FIG. 5 shows a cross-sectional view of a multi-die semiconductor device according to an aspect of the present disclosure;

FIG. 6 shows a top-down view of a multi-die semiconductor device according to an aspect of the present disclosure;

FIG. 7 shows an illustration of a computing device that includes a semiconductor device according to a further aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for the present devices, and various aspects are provided for the methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

These and other aforementioned advantages and features of the aspects herein disclosed will be apparent through reference to the following description and the accompanying drawings. Furthermore, it is to be understood that the features of the various aspects described herein are not mutually exclusive and can exist in various combinations and permutations.

The present disclosure generally relates to a device. The device may include a printed circuit board a carrier with a plurality of first bump pads. The device may also include a first die with a plurality of second bump pads. The device may also include a plurality of first bumps disposed between the plurality of first bump pads and the plurality of second bump pads to electrically connect the first die to the carrier. The device may also include solder disposed between the plurality of first bump pads and the plurality of second bump pads, wherein the plurality of first bump pads have a first pitch relative to one another, and the plurality of second bump pads have a second pitch relative to one another, and wherein the first pitch is different from the second pitch. Each first bump pad of the plurality of first bump pads is larger than each second bump pad of the plurality of second bump pads.

The present disclosure generally relates to a method of forming a device. The method may include providing a carrier with a plurality of first bump pads. The method may also include providing a first die with a plurality of second bump pads. The method may also include disposing a plurality of first bumps between the plurality of first bump pads and the plurality of second bump pads to electrically connect the first die to the carrier. The method may also include disposing solder between the plurality of first bump pads and the plurality of second bump pads, wherein the plurality of first bump pads have a first pitch relative to one another, and the plurality of second bump pads have a second pitch relative to one another, and wherein the first pitch is different from the second pitch. Each first bump pad of the plurality of first bump pads is larger than each second bump pad of the plurality of second bump pads.

To more readily understand and put into practical effect, the present device, method, and other particular aspects will now be described by way of examples and not limitations, and with reference to the figures. For the sake of brevity, duplicate descriptions of features and properties may be omitted.

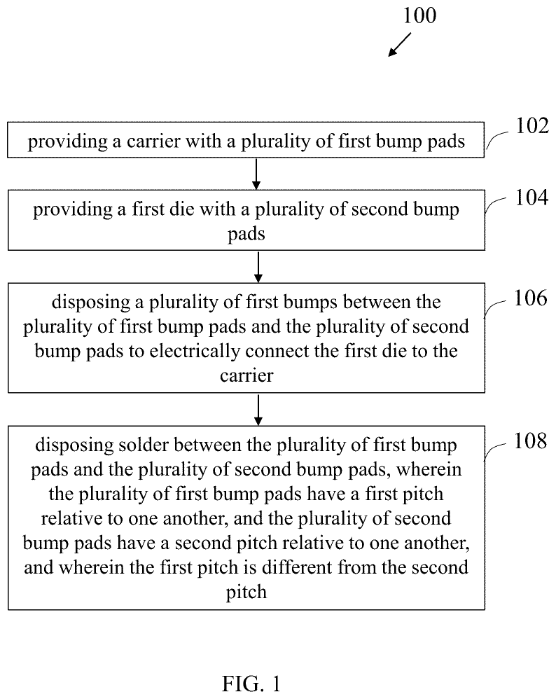

FIG. 1 shows a flow chart illustrating a method of forming a semiconductor device according to an aspect of the present disclosure.

As shown in FIG. 1, there may be a method 100 of forming a device. In the method 100, a first operation 102 may include providing a carrier with a plurality of first bump pads. A second operation 104 may include providing a first die with a plurality of second bump pads. A third operation 106 may include disposing a plurality of first bumps between the plurality of first bump pads and the plurality of second bump pads to electrically connect the first die to the carrier. A fourth operation 108 may include disposing solder between the plurality of first bump pads and the plurality of second bump pads, wherein the plurality of first bump pads have a first pitch relative to one another, and the plurality of second bump pads have a second pitch relative to one another, and wherein the first pitch is different from the second pitch. Each first bump pad of the plurality of first bump pads is larger than each second bump pad of the plurality of second bump pads.

It will be understood that the above operations described above relating to FIG. 1 are not limited to this particular order. Any suitable, modified order of operations may be used.

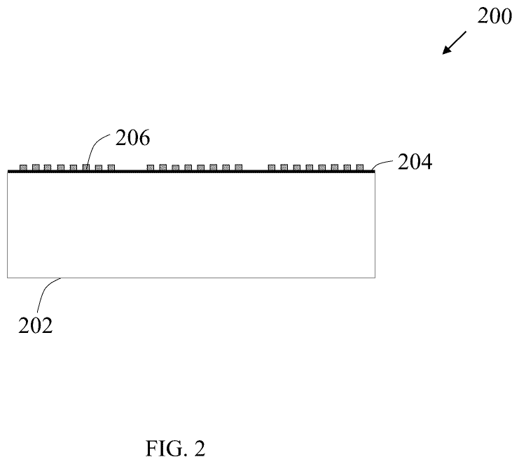

FIG. 2 shows a cross-sectional view of a semiconductor carrier according to an aspect of the present disclosure.

In an aspect of the present disclosure, a semiconductor device 200 is shown in FIG. 2.

In an aspect of the present disclosure, the semiconductor device 200 may include a carrier 202 which may be a package substrate. The carrier 202 may be glass or silicon.

In an aspect of the present disclosure, the semiconductor device 200 may include a release layer 204. In an aspect, a plurality of first bump pads 206 may be disposed on the release layer 204. The plurality of first bump pads 206 may be lithographically defined. The bump pads 206 may be a contact pad for a plurality of bumps to be disposed on. The plurality of first bump pads 206 may have a pitch of between 40-60 um.

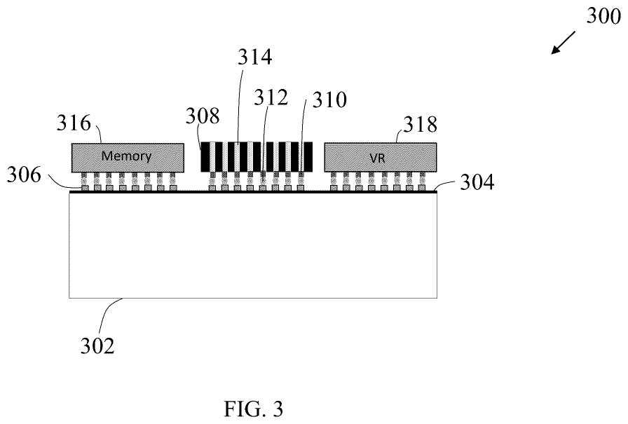

FIG. 3 shows a cross-sectional view of a semiconductor device according to an aspect of the present disclosure.

In an aspect of the present disclosure, a semiconductor device 300 is shown in FIG. 3.

In an aspect of the present disclosure, the semiconductor device 300 may include a carrier 302 which may be a package substrate. The carrier 302 may be glass or silicon.

In an aspect of the present disclosure, the semiconductor device 300 may include a release layer 304. In an aspect, a plurality of first bump pads 306 may be disposed on the release layer 304. The plurality of first bump pads 306 may be lithographically defined. The plurality of first bump pads 306 may have a pitch of between 40-60 um.

In an aspect of the present disclosure, the semiconductor device 300 may include a first die 308. The first die 308 may be made from any suitable semiconductor, such as silicon or gallium arsenide. The first die 308 may be a semiconductor die, a chip or a set of chiplets, e.g., a system-on-chip (SOC), a platform controller hub (PCH)/chipset, a memory device, a field programmable gate array (FPGA) device, a central processing unit (CPU), or a graphic processing unit (GPU). The first die 308 may be an active device or a passive device.

In an aspect of the present disclosure, the first die 308 may have a plurality of second bump pads 310. The plurality of second bump pads 310 may be lithographically defined on the bottom of the first die 308.

In an aspect of the present disclosure, a plurality of first bumps 312 may be disposed between the plurality of first bump pads 306 and the plurality of second bump pads 310 to electrically connect the first die 308 to the carrier 302.

In an aspect of the present disclosure, solder (e.g., liquidous solder) is disposed between the plurality of first bump pads 306 and the plurality of second bump pads 310 to physically self-align the plurality of first bump pads 306, the plurality of second bump pads 310 and the plurality of first bumps 312 through surface tension of the solder. Each first bump pad of the plurality of first bump pads 306 may be larger than each second bump pad of the plurality of second bump pads 310. In an aspect of the present disclosure, the solder is disposed through mass reflow. The solder (not depicted) is disposed between the plurality of first bump pads 306, the plurality of first bumps 312 and the plurality of second bump pads 310. The solder along with the plurality of first bump pads 306, the plurality of first bumps 312 and the plurality of second bump pads 310 electrically connects and physically aligns the first die 308 to the carrier 302.

In an aspect of the present disclosure, the plurality of first bump pads 306 and the plurality of second bump pads 310 may have a different pitch. The first bump pad pitch may be larger, for mechanical properties to self-align the first die when doing solder mass-reflow. In an aspect, the plurality of first bump pads may have a first pitch relative to one another, and the plurality of second bump pads may have a second pitch relative to one another, and wherein the first pitch is different from the second pitch. In an aspect, the first pitch may be larger than the second pitch.

In an aspect, the first bumps may be placed onto pads that are defined with lithography on the carrier. The first bump pad lithography on the carrier may be very accurate for bump-to-bump alignment, as it is driven by a mask process with a large reticle size that covers the entire semiconductor device. That is the first level of relative accuracy. The first die then use a die attach placement process to land on the first bump pads on the carrier. The first bumps may use a solder connection that can then physically align the first die with the surface tension of the solder. The first die also align well relative to each other due to the accuracy of the pads as described above. The first bumps may be solder balls. The first bumps may provide electrical connection between the carrier 302 and the first die 308.

In an aspect of the present disclosure, the first die 308 may include a plurality of through silicon vias 314.

In an aspect of the present disclosure, the semiconductor device 300 may include a memory 316 and a voltage regulator 318.

In an aspect of the present disclosure, the memory 316 may have the plurality of second bump pads 310 disposed on the bottom. The plurality of first bumps 312 may be disposed between the second bump pads 310 and the first bump pads 306 to electrically connect the memory 316 to the carrier 302.

In an aspect of the present disclosure, the voltage regulator 318 may have the plurality of second bump pads 310 disposed on the bottom. The plurality of first bumps 312 may be disposed between the second bump pads 310 and the first bump pads 306 to electrically connect the voltage regulator 318 to the carrier 302.

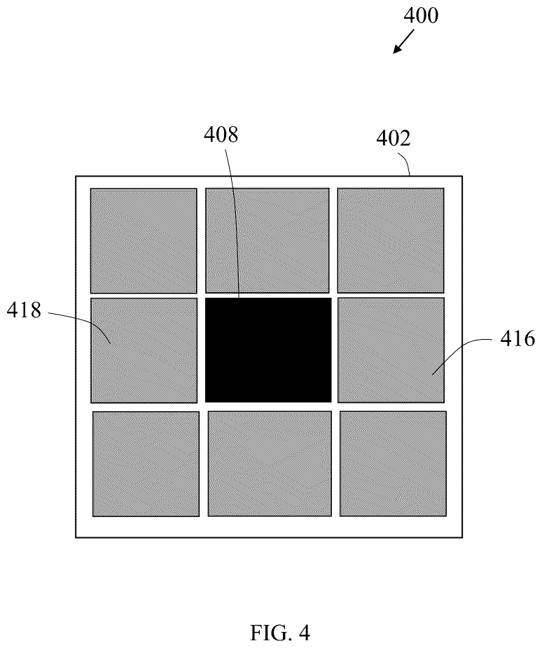

FIG. 4 shows a top-down view of a semiconductor device according to an aspect of the present disclosure.

In an aspect of the present disclosure, a semiconductor device 400 is shown in FIG. 4. The semiconductor 400 includes a first die 408, a memory 416 and a voltage regular 418 as described in FIG. 3.

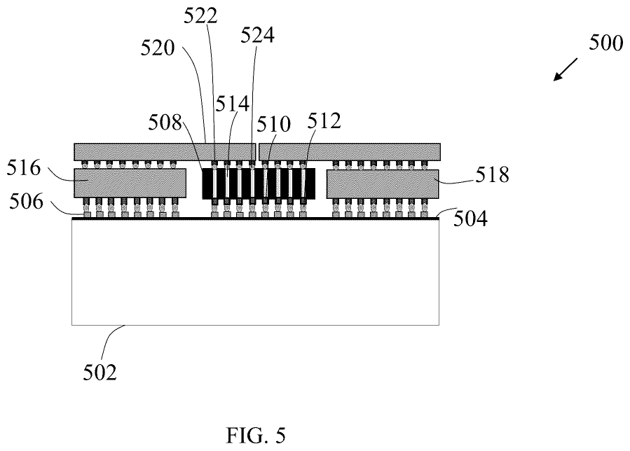

FIG. 5 shows a cross-sectional view of a multi-die semiconductor device according to an aspect of the present disclosure.

In an aspect of the present disclosure, a semiconductor device 500 is shown in FIG. 5.

In an aspect of the present disclosure, the semiconductor device 500 may include a carrier 502 which may be a package substrate. The carrier 502 may be glass or silicon.

In an aspect of the present disclosure, the semiconductor device 500 may include a release layer 504. In an aspect, a plurality of first bump pads 506 may be disposed on the release layer 504. The plurality of first bump pads 506 may be lithographically defined. The plurality of first bump pads 506 may be precise circular pads. The plurality of first bump pads 506 may have a pitch of between 40-60 um.

In an aspect of the present disclosure, the semiconductor device 500 may include a first die 508. The first die 508 may be made from any suitable semiconductor, such as silicon or gallium arsenide. The first die 508 may be a semiconductor die, a chip or a set of chiplets, e.g., a system-on-chip (SOC), a platform controller hub (PCH)/chipset, a memory device, a field programmable gate array (FPGA) device, a central processing unit (CPU), or a graphic processing unit (GPU).

In an aspect of the present disclosure, the first die 508 may have a plurality of second bump pads 510. The plurality of second bump pads 510 may be lithographically defined on the bottom of the first die 508.

In an aspect of the present disclosure, a plurality of first bumps 512 may be disposed between the plurality of first bump pads 506 and the plurality of second bump pads 510 to electrically connect the first die 508 to the carrier 502.

In an aspect of the present disclosure, solder (e.g., liquidous solder) is disposed between the plurality of first bump pads 506 and the plurality of second bump pads 510 to physically self-align the plurality of first bump pads 506, the plurality of second bump pads 510 and the plurality of first bumps 512 through surface tension of the solder. Each first bump pad of the plurality of first bump pads 506 may be larger than each second bump pad of the plurality of second bump pads 510. The pitch and size of the first pads can be larger than the second pads and still achieve the self-alignment with enough precision for top pads of the first die to align with <25 um pitch (alignment accuracy+/−˜6-7 um). For the first bumps, the diameter/size may be larger as it is the solder surface tension that is the self-aligning mechanism, so the larger the bump size the more solder for self-alignment force. In an aspect, the first pitch may be larger than the second pitch.

In an aspect of the present disclosure, the first die 508 may include a plurality of through silicon vias 514.

In an aspect of the present disclosure, the semiconductor device 500 may include a memory 516 and a voltage regulator 518. The memory 516 and the a voltage regulator 518 may require dual sided lithography with precision within each other, which is achievable with wafer level processing or with TSV exposure on thinned silicon.

In an aspect of the present disclosure, the memory 516 may have the plurality of second bump pads 510 disposed on the bottom. The plurality of first bumps 512 may be disposed between the second bump pads 510 and the first bump pads 506 to electrically connect the memory 516 to the carrier 502.

In an aspect of the present disclosure, the voltage regulator 518 may have the plurality of second bump pads 510 disposed on the bottom. The plurality of first bumps 512 may be disposed between the second bump pads 510 and the first bump pads 506 to electrically connect the voltage regulator 518 to the carrier 502.

In an aspect of the present disclosure, a second die 520 may have a plurality of third bump pads 522. The plurality of third bump pads 522 may be lithographically defined on the bottom of the first die 520. The second die 520 may be an active device or a passive device.

The second die 520 may be attached with mass-reflow, thermo-compression bonding, or D2W Hybrid Bonding with alignment to a first die collective of heterogenous silicon devices (high melting solder or IMC for die gap oxide filling, CMP and hybrid bonding process).

In an aspect of the present disclosure, a plurality of second bumps 524 may be disposed between the plurality of third bump pads 522 and the plurality of through silicon vias 514 to electrically connect the second die 520 to the first die 508. The first die 508 and the second die 520 may be of different sizes. The second die field and the first die field can be architecture independent of each other and the first die and the second die can be configured in multiple ways to take advantage of this independence. Also, there is no limitation to only two layers of silicon dies, and it can be continued with more die stacking with TSV or TMV interconnects.

In an aspect of the present disclosure, the memory 516 may be disposed adjacent to the first die 508. The memory 516 may be electrically connected to the second die 520.

In an aspect of the present disclosure, the voltage regulator 518 may be disposed adjacent to the first die 508. The voltage regulator 518 may be electrically connected to the second die 520.

In an aspect of the present disclosure, the carrier 502 may be patterned with first bump pads 506 and the mass-reflow solder attach will allow for self-alignment. The second die 520 may be placed on a top surface of the first die 508 (or with added RDL layer) to achieve interconnect pitch in the 10-25 um range.

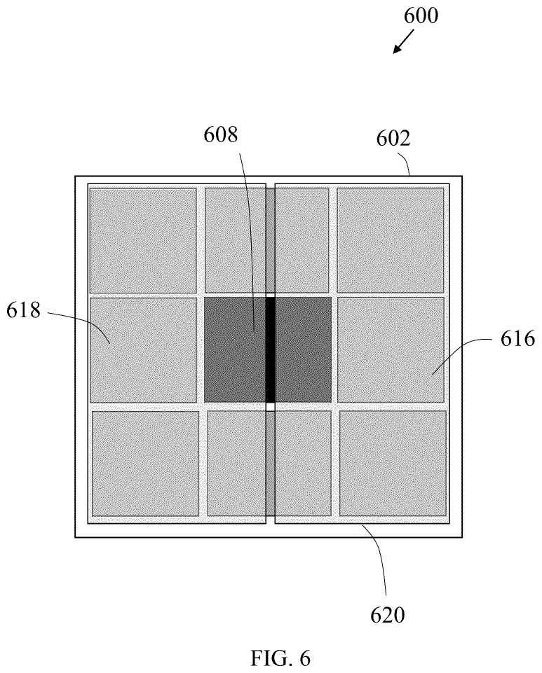

FIG. 6 shows a top-down view of a multi-die semiconductor device according to an aspect of the present disclosure.

In an aspect of the present disclosure, a top down view of a semiconductor device 600 is shown in FIG. 6. The semiconductor 600 includes a first die 608, a memory 616 and a voltage regular 618, a second die 520 as described in FIG. 5.

Aspects of the present disclosure may be implemented into a system using any suitable hardware and/or software.

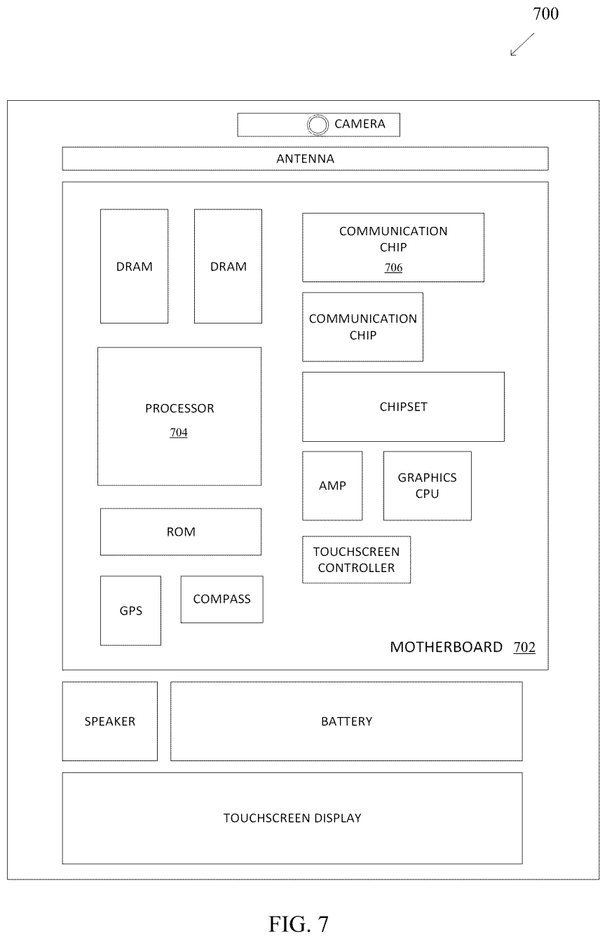

FIG. 7 schematically illustrates a computing device 700 that may include a semiconductor device as described herein, in accordance with some aspects.

As shown in FIG. 7, the computing device 700 may house a board such as a motherboard 702. The motherboard 702 may include a number of components, including but not limited to a processor 704 and at least one communication chip 706. The processor 704 may be physically and electrically coupled to the motherboard 702. In some implementations, the at least one communication chip 706 may also be physically and electrically coupled to the motherboard 702. In further implementations, the communication chip 706 may be part of the processor 704.

Depending on its applications, the computing device 700 may include other components that may or may not be physically and electrically coupled to the motherboard 702. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the processor 704 of the computing device 700 may be packaged in a semiconductor package, as described herein, and/or other semiconductor devices may be packaged together in a semiconductor package as described herein.

The communication chip 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 706 may implement any of a number of wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 706 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 706 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 706 may operate in accordance with other wireless protocols in other aspects.

The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In an aspect, the computing device 700 may be a mobile computing device. In further implementations, the computing device 700 may be any other electronic device that processes data.

### EXAMPLES

Example 1 may include a device including: a carrier with a plurality of first bump pads; a first die with a plurality of second bump pads; a plurality of first bumps disposed between the plurality of first bump pads and the plurality of second bump pads to electrically connect the first die to the carrier; solder disposed between the plurality of first bump pads and the plurality of second bump pads, wherein the plurality of first bump pads have a first pitch relative to one another, and the plurality of second bump pads have a second pitch relative to one another, and wherein the first pitch is different from the second pitch; and wherein each first bump pad of the plurality of first bump pads is larger than each second bump pad of the plurality of second bump pads.

Example 2 may include the device of example 1 and/or any other example disclosed herein, wherein the first pitch is larger than the second pitch.

Example 3 may include the device of example 1 and/or any other example disclosed herein, wherein the solder is disposed through mass reflow.

Example 4 may include the device of example 1 and/or any other example disclosed herein, wherein the first die includes a plurality of through silicon vias.

Example 5 may include the device of example 4 and/or any other example disclosed herein, further including a second die disposed on and electrically connected to the first die.

Example 6 may include the device of example 5 and/or any other example disclosed herein, wherein the second die includes a plurality of third bump pads disposed on a bottom surface of the second die.

Example 7 may include the device of example 6 and/or any other example disclosed herein, further including a plurality of second bumps disposed between the plurality of through silicon vias and the plurality of third bump pads to electrically connect the first die to the second die.

Example 8 may include the device of example 5 and/or any other example disclosed herein, wherein the first die and the second die are of different sizes.

Example 9 may include the device of example 5 and/or any other example disclosed herein, further including a memory disposed adjacent to the first die, wherein the memory is electrically connected to the second die.

Example 10 may include the device of example 5 and/or any other example disclosed herein, further including a voltage regulator disposed adjacent to the first die, wherein the voltage regulator is electrically connected to the second die.

Example 11 may include a method including providing a carrier with a plurality of first bump pads; providing a first die with a plurality of second bump pads; disposing a plurality of first bumps between the plurality of first bump pads and the plurality of second bump pads to electrically connect the first die to the carrier; disposing solder between the plurality of first bump pads and the plurality of second bump pads, wherein the plurality of first bump pads have a first pitch relative to one another, and the plurality of second bump pads have a second pitch relative to one another, and wherein the first pitch is different from the second pitch; and wherein each first bump pad of the plurality of first bump pads is larger than each second bump pad of the plurality of second bump pads.

Example 12 may include the method of example 11 and/or any other example disclosed herein, wherein the first pitch is larger than the second pitch.

Example 13 may include the method of example 11 and/or any other example disclosed herein, further including disposing the solder through mass reflow.

Example 14 may include the method of example 11 and/or any other example disclosed herein, wherein the first die includes a plurality of through silicon vias.

Example 15 may include the method of example 14 and/or any other example disclosed herein, further including disposing and electrically connecting a second die to the first die.

Example 16 may include the method of example 15 and/or any other example disclosed herein, further including disposing a plurality of third bump pads on a bottom surface of the second die.

Example 17 may include the method of example 16 and/or any other example disclosed herein, further including disposing a plurality of second bumps disposed between the plurality of through silicon vias and the plurality of third bump pads to electrically connect the first die to the second die.

Example 18 may include the method of example 15 and/or any other example disclosed herein, wherein the first die and the second die are of different sizes.

Example 19 may include the method of example 15 and/or any other example disclosed herein, further including disposing a memory adjacent to the first die, and electrically connecting the memory to the second die.

Example 20 may include the method of example 15 and/or any other example disclosed herein, further including disposing a voltage regulator adjacent to the first die, and electrically connecting the voltage regulator to the second die.

These and other advantages and features of the aspects herein disclosed will be apparent through reference to the following description and the accompanying drawings. Furthermore, it is to be understood that the features of the various aspects described herein are not mutually exclusive and can exist in various combinations and permutations.

It will be understood that any property described herein for a specific system or device may also hold for any system or device described herein. It will also be understood that any property described herein for a specific method may hold for any of the methods described herein. Furthermore, it will be understood that for any device, system, or method described herein, not necessarily all the components or operations described will be enclosed in the device, system, or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a carrier with a plurality of first bump pads;
a first die with a plurality of second bump pads;
a plurality of first bumps disposed between the plurality of first bump pads and the plurality of second bump pads to electrically connect the first die to the carrier;
solder disposed between the plurality of first bump pads and the plurality of second bump pads, wherein the plurality of first bump pads have a first pitch relative to one another, and the plurality of second bump pads have a second pitch relative to one another, and wherein the first pitch is different from the second pitch; and
wherein each first bump pad of the plurality of first bump pads is larger than each second bump pad of the plurality of second bump pads.

2. The device of claim 1, wherein the first pitch is larger than the second pitch.

3. The device of claim 1, wherein the solder is disposed through mass reflow.

4. The device of claim 1, wherein the first die comprises a plurality of through silicon vias.

5. The device of claim 4, further comprising:
a second die disposed on and electrically connected to the first die.

6. The device of claim 5, wherein the second die comprises a plurality of third bump pads disposed on a bottom surface of the second die.

7. The device of claim 6, further comprising:
a plurality of second bumps disposed between the plurality of through silicon vias and the plurality of third bump pads to electrically connect the first die to the second die.

8. The device of claim 5, wherein the first die and the second die are of different sizes.

9. The device of claim 5, further comprising:
a memory disposed adjacent to the first die, wherein the memory is electrically connected to the second die.

10. The device of claim 5, further comprising:
a voltage regulator disposed adjacent to the first die, wherein the voltage regulator is electrically connected to the second die.

11. A method comprising:
providing a carrier with a plurality of first bump pads;
providing a first die with a plurality of second bump pads;
disposing a plurality of first bumps between the plurality of first bump pads and the plurality of second bump pads to electrically connect the first die to the carrier;
disposing solder between the plurality of first bump pads and the plurality of second bump pads, wherein the plurality of first bump pads have a first pitch relative to one another, and the plurality of second bump pads have a second pitch relative to one another, and wherein the first pitch is different from the second pitch; and
wherein each first bump pad of the plurality of first bump pads is larger than each second bump pad of the plurality of second bump pads.

12. The method of claim 11, wherein the first pitch is larger than the second pitch.

13. The method of claim 11, further comprising:
disposing the solder through mass reflow.

14. The method of claim 11, wherein the first die comprises a plurality of through silicon vias.

15. The method of claim 14, further comprising:
disposing and electrically connecting a second die to the first die.

16. The method of claim 15, further comprising:
disposing a plurality of third bump pads on a bottom surface of the second die.

17. The method of claim 16, further comprising:
disposing a plurality of second bumps disposed between the plurality of through silicon vias and the plurality of third bump pads to electrically connect the first die to the second die.

18. The methods of claim 15, wherein the first die and the second die are of different sizes.

19. The method of claim 15, further comprising:
disposing a memory adjacent to the first die, and electrically connecting the memory to the second die.

20. The method of claim 15, further comprising:
disposing a voltage regulator adjacent to the first die, and electrically connecting the voltage regulator to the second die.
